(19) United States
(12) Patent Application Publication
(10) Pub. No.: US 2013/0075553 A1
(43) Pub. Date: Mar. 28, 2013

(54) Method and Apparatus for Coupling and Decoupling an Electronic Device with a Surface

(71) Applicant: Jukka Olavi RAUTIAINEN, Helsinki (FI)

(72) Inventor: Jukka Olavi RAUTIAINEN, Helsinki (FI)

(73) Assignee: NOKIA CORPORATION, Espoo (FI)

(21) Appl. No.: 13/246,246

(22) Filed: Sep. 27, 2011

(51) Int. Cl. H05K 7/00; B23P 11/00; F16B 47/00

(52) U.S. Cl. 248/205.8; 29/428

(57) ABSTRACT

An apparatus comprises a suction portion having a suction element and a protruded portion, a base portion having an opening for receiving said protruded portion, a lever having first and second ends, said lever coupled with said protruded portion, said lever capable of interfacing with said base portion and moving said suction portion with respect to said base portion into open and closed configurations, said lever having an open position and a closed position, said lever capable of causing said suction portion to move with respect to said base portion into said open configuration when said lever is pressed proximate to said first end, said lever capable of causing said suction portion to move with respect to said base portion into said closed configuration when said lever is pressed proximate to said second end.

### TECHNICAL FIELD

The present application relates generally to a method and apparatus for coupling and decoupling an electronic device with a surface.

### BACKGROUND

Various types of electronic devices such as global positioning receivers, mobile communication devices and radar detectors are used in automobiles. Electronic devices are routinely mounted to various surfaces within the automobile such as a dashboard or a windshield. Some electronic devices are mounted within automobiles using a suction mechanism.

### SUMMARY

Various aspects of examples of the invention are set out in the claims.

According to a first aspect of the present invention, an apparatus comprises a suction portion having a suction element and a protruded portion, a base portion having an opening for receiving said protruded portion, a lever having first and second ends, said lever coupled with said protruded portion, said lever capable of interfacing with said base portion and moving said suction portion with respect to said base portion into open and closed configurations, said lever having an open position and a closed position, said lever capable of causing said suction portion to move with respect to said base portion into said open configuration when said lever is pressed proximate to said first end, said lever capable of causing said suction portion to move with respect to said base portion into said closed configuration when said lever is pressed proximate to said second end, and a housing portion for housing at least said base portion having an exterior surface and an opening for said lever, said lever being substantially flush with said housing portion when said lever is in said closed position.

According to a second aspect of the present invention, a method comprises transforming an apparatus from a closed configuration to an open configuration by pressing a lever proximate to a first end of said lever, wherein said apparatus comprises a suction portion having a suction element and a protruded portion, a base portion having an opening for receiving said protruded portion, said lever having said first end and a second end, said lever coupled with said protruded portion, said lever capable of interfacing with said base portion and moving said suction portion with respect to said base portion into open and closed configurations, said lever having an open position and a closed position, said lever capable of causing said suction portion to move with respect to said base portion into said open configuration when said lever is pressed proximate to said first end, said lever capable of causing said suction portion to move with respect to said base portion into said closed configuration when said lever is pressed proximate to said second end.

According to a third aspect of the present invention, an apparatus, comprises a coupling means for coupling a device with a surface having a protruded portion, a base portion having an opening for receiving said protruded portion, a decoupling means having first and second ends, said decoupling means coupled with said protruded portion, said decoupling means capable of interfacing with said base portion and moving said coupling means with respect to said base portion into open and closed configurations, said decoupling means having an open position and a closed position, said decoupling means capable of causing said coupling means to move with respect to said base portion into said open configuration when said decoupling means is actuated proximate to said first end, said decoupling means capable of causing said coupling means to move with respect to said base portion into said closed configuration when said decoupling means is actuated proximate to said second end.

### BRIEF DESCRIPTION OF THE DRAWINGS

For a more complete understanding of example embodiments of the present invention, reference is now made to the following descriptions taken in connection with the accompanying drawings in which:

FIG. 1a is a side view of an apparatus comprising an electronic device coupler according to an example embodiment of the invention;

FIG. 1b is a top view of the apparatus of FIG. 1a according to an example embodiment of the invention;

FIG. 1c is a perspective view of the apparatus of FIG. 1a according to an example embodiment of the invention;

FIG. 2a is a side view of an apparatus comprising a lever in an open position according to an example embodiment of the invention;

FIG. 2b is a side view of the apparatus of FIG. 2a comprising a lever in a closed position according to an example embodiment of the invention;

FIG. 2c is a perspective view of the apparatus of FIG. 2a comprising a lever in an open position according to an example embodiment of the invention;

FIG. 2d is a perspective view of the apparatus of FIG. 2a comprising a lever in a closed configuration according to an example embodiment of the invention;

FIG. 3a is an exploded perspective view of an apparatus according to an example embodiment of the invention;

FIG. 3b is an exploded side view of an apparatus according to an example embodiment of the invention;

FIG. 3c is an exploded front view of an apparatus according to an example embodiment of the invention; and

FIG. 4 is flow diagram illustrating a method according to an example embodiment of the invention.

### DETAILED DESCRIPTION OF THE DRAWINGS

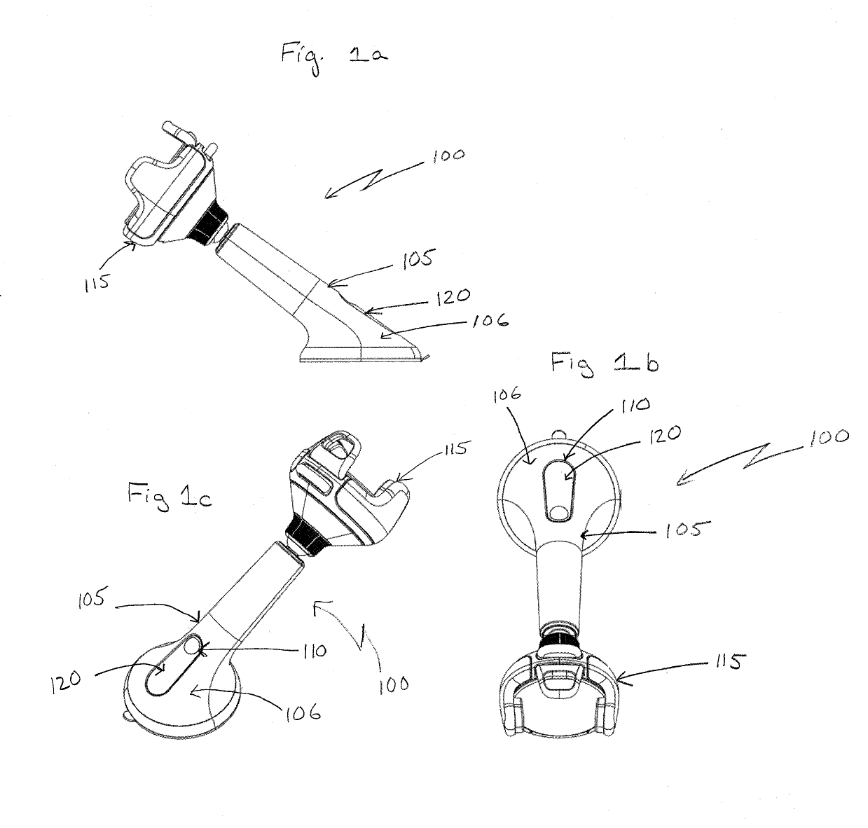

An example embodiment of the present invention and its potential advantages are understood by referring to FIGS. 1 through 4 of the drawings.

FIG. 1a is a side view of an apparatus 100 comprising an electronic device coupler such as electronic device coupler 115 according to an example embodiment of the invention. FIG. 1b is a top view of the apparatus 100 of FIG. 1a according to an example embodiment of the invention. FIG. 1c is a perspective view of the apparatus 100 of FIG. 1a according to an example embodiment of the invention. In an embodiment, apparatus 100 comprises a base portion and a housing portion 105 for housing at least the base portion. In an embodiment, the housing portion 105 has an exterior surface 106 and an opening such as opening 110 for a lever such as lever 120.

In an embodiment, an apparatus such as apparatus 100 couples an electronic device such as a GPS receiver, communication device, radar detector, and/or the like with a surface such as an interior surface within an automobile, for example, a dashboard or windshield. Apparatus 100 may couple an electronic device in any way including the use of a clamping mechanism, fastener, bolt and/or any other type of coupling mechanism. In an embodiment, apparatus 100 couples electronic device with a surface using a suction mechanism.

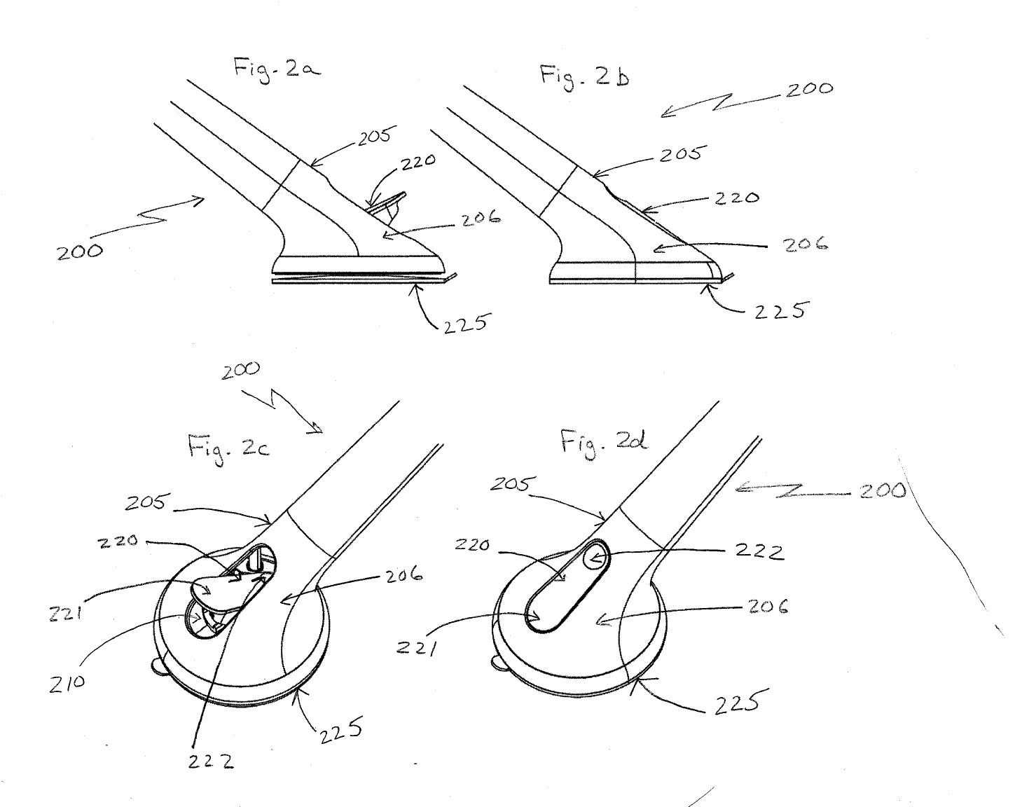

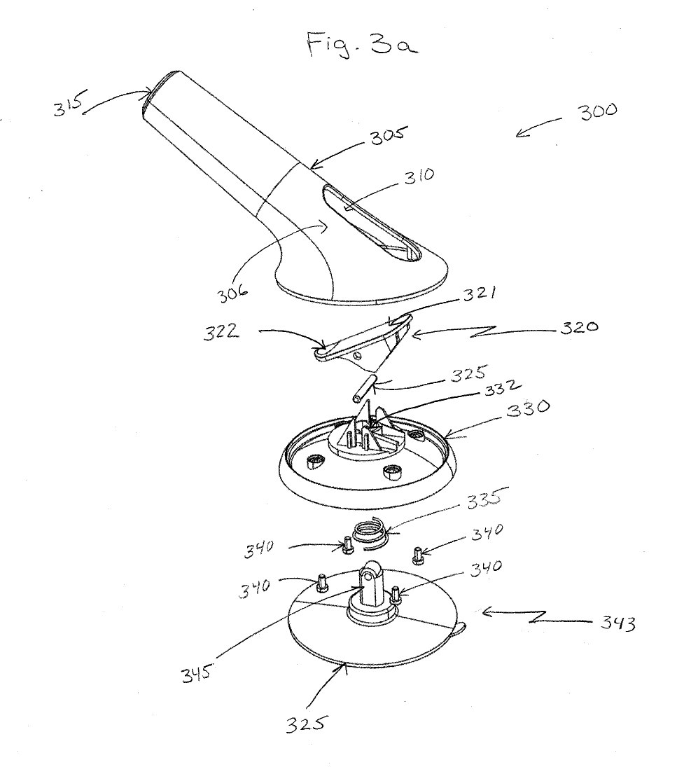

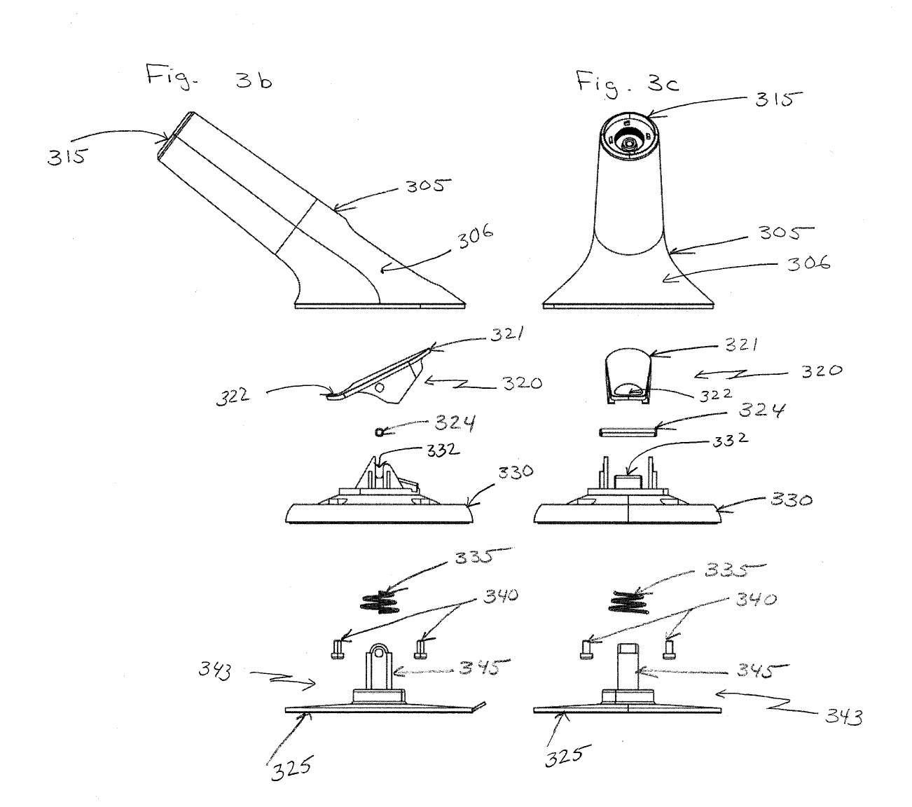

FIG. 2a is a side view of an apparatus 200 comprising a lever 220 in an open position according to an example embodiment of the invention. FIG. 2b is a side view of apparatus 200 of FIG. 2a comprising a lever 220 in a closed position according to an example embodiment of the invention. FIG. 2c is a perspective view of apparatus 200 of FIG. 2a comprising a lever 220 in an open position according to an example embodiment of the invention. FIG. 2d is a perspective view of apparatus 200 of FIG. 2a comprising a lever in a closed configuration according to an example embodiment of the invention.

In an embodiment, apparatus 200 comprises a suction portion having a suction element 225, a base portion, a lever 220 and a housing portion 205 for housing at least the base portion. In an embodiment, the lever is capable of interfacing with the base portion and moving the suction portion with respect to the base portion into open and closed configurations. The lever 220 has an open position as shown in FIGS. 2a and 2c. Further, lever 220 has a closed position as shown in FIGS. 2b and 2d. In an embodiment, lever 220 is capable of causing the suction portion to move with respect to the base portion into an open configuration when lever 220 is pressed proximate to an end such as end 222. In an embodiment, lever 220 is capable of causing the suction portion to move with respect to the base portion into a closed configuration when lever 220 is pressed proximate to an end such as end 221.

In an embodiment, the housing portion 205 has an exterior surface 206 and an opening such as opening 210 for a lever such as lever 220. In an embodiment, according to FIGS. 2b and 2d, lever 220 is substantially flush with housing portion 205 when lever 220 is in a closed position.

In an embodiment, an apparatus 200 couples an electronic device such as a GPS receiver, communication device, radar detector, and/or the like with a surface such as an interior surface within an automobile, for example, a dashboard or windshield. In an embodiment, apparatus 200 comprises an electronic device coupler such as electronic device coupler 215 for removeably coupling an electronic device with the apparatus 200. Apparatus 200 may couple an electronic device in any way including the use of a clamping mechanism, fastener, bolt and/or any other type of coupling mechanism. In an embodiment, apparatus 200 couples electronic device with a surface using a suction mechanism such as a suction portion having a suction element 225. In an embodiment, a suction portion is capable of detachably coupling the apparatus to a surface when lever 220 is in a closed position. In an embodiment, the suction portion is capable of detaching apparatus 200 from a surface when lever 220 is in an open position.

In an embodiment, lever 220 is capable of being pressed with a finger proximate to end 222 to cause the suction portion to move to an open configuration. In an embodiment, lever 220 is capable of being pressed with a finger proximate to end 221 to cause the suction portion to move to a closed configuration. In an embodiment, lever 220 is capable of being pressed with a finger proximate to end 222 to cause the suction portion to move to an open configuration and the lever 220 is further capable of being pressed with the same finger proximate to end 221 to cause the suction portion to move to a closed configuration.

In an embodiment, apparatus 200 of FIGS. 2a, 2b, 2c and 2d is apparatus 100 of FIGS. 1a, 1b and 1c.

FIG. 3a is an exploded perspective view of an apparatus 300 according to an example embodiment of the invention. FIG. 3b is an exploded side view of an apparatus 300 according to an example embodiment of the invention. FIG. 3c is an exploded front view of an apparatus according to an example embodiment of the invention.

In an embodiment, apparatus 300 comprises a suction portion 343 having a suction element 325 and a protruded portion 345, a base portion 330 having an opening 332 for receiving protruded portion 345 and a lever 320 having end 322 and end 321. In an embodiment, lever 320 is coupled with the protruded portion 345. In an embodiment, the lever 320 is capable of interfacing with the base portion 330 and moving the suction portion 343 with respect to the base portion 330 into open and closed configurations. In an embodiment, the lever 320 has an open position such as the open position of FIG. 2c and a closed position such as the closed position of FIG. 2d. In an embodiment, the lever 320 is capable of causing the suction portion 343 to move with respect to the base portion 330 into an open configuration when the lever 320 is pressed proximate to end 322. In an embodiment, the lever is capable of causing suction portion 343 to move with respect to base portion 330 into a closed configuration when lever 320 is pressed proximate to said end 321. In an embodiment, apparatus 300 further comprises a housing portion 305 for housing at least said base portion 330 having an exterior surface 306 and an opening 310 for lever 320. In an embodiment, lever 320 is substantially flush with exterior surface 306 when lever 320 is in a closed position.

In an embodiment, when lever 320 is pressed at end 322, lever 320 pushes protruded portion 345 and moves apparatus 300 toward an open configuration. In an embodiment, when lever 320 is pressed at end 321, lever 320 pulls protruded portion 345 and moves apparatus 300 toward a closed configuration.

In an embodiment, apparatus 300 further comprises a pin 324 coupled with protruded portion 345 and lever 320. In an embodiment, apparatus 300 further comprises at least one fastener such as screws 340 for coupling base portion 330 with housing portion 305.

In an embodiment, apparatus 300 couples an electronic device such as a GPS receiver, communication device, radar detector, and/or the like with a surface such as an interior surface within an automobile, for example, a dashboard or windshield. In an embodiment, apparatus 300 comprises an electronic device coupler such as electronic device coupler 315 for removeably coupling an electronic device with the apparatus 300. Apparatus 300 may couple an electronic device in any way including the use of a clamping mechanism, fastener, bolt and/or any other type of coupling mechanism.

In an embodiment, apparatus 300 couples electronic device with a surface using a suction mechanism such as a suction portion 343 having a suction element 325. In an embodiment, a suction portion 343 is capable of detachably coupling the apparatus to a surface when at least one of lever 320 is in a closed position and apparatus 300 is in a closed configuration. In an embodiment, the suction portion 343 is capable of detaching apparatus 300 from a surface when at least one of lever 320 is in an open position and apparatus 300 is in an open configuration. In an embodiment, lever 320 protrudes through opening 332 when lever 320 is in an open position as shown in FIG. 2c.

In an embodiment, lever 320 is capable of being pressed with a finger proximate to end 322 to cause the suction portion to move to an open configuration. In an embodiment, lever 320 is capable of being pressed with a finger proximate to end 321 to cause suction portion 325 to move to a closed configuration. In an embodiment, lever 320 is capable of being pressed with a finger proximate to end 322 to cause suction portion 325 to move to an open configuration and the lever 320 is further capable of being pressed with the same finger proximate to end 321 to cause suction portion 325 to move to a closed configuration.

In an embodiment, apparatus comprises a resilient member such as spring 330 positioned with protruded portion 345 capable of biasing suction portion 343 toward an open configuration.

In an embodiment, a contour of an exterior surface of lever 320 is substantially similar to a contour of exterior surface 306 of housing portion 305.

In an embodiment, apparatus 300 of FIGS. 3a, 3b and 3c is apparatus 100 of FIGS. 1a, 1b and 1c. In an embodiment, apparatus 300 of FIGS. 3a, 3b and 3c is apparatus 200 of FIGS. 2a, 2b, 2c and 2d.

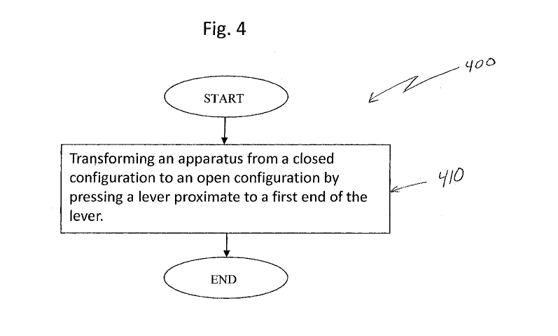

FIG. 4 is flow diagram illustrating a method 400 according to an example embodiment of the invention. In an embodiment, at 410, a method 400 comprises transforming an apparatus such as apparatus 100 of FIG. 1a from a closed configuration such as the closed configuration of FIG. 2d to an open configuration such as the open configuration of FIG. 2c by pressing a lever such as lever 220 of FIG. 2d proximate to a first end of said lever such as end 322. In the embodiment, the apparatus such as apparatus 300 of FIG. 3 comprises a suction portion 343 having a suction element 325 and a protruded portion 345, a base portion 330 having an opening 332 for receiving protruded portion 345 and a lever 320 having end 322 and end 321. In an embodiment, lever 320 is coupled with the protruded portion 345. In an embodiment, the lever 320 is capable of interfacing with the base portion 330 and moving suction portion 343 with respect to the base portion 330 into open and closed configurations. In an embodiment, the lever 320 has an open position such as the open position of FIG. 2c and a closed position such as the closed position of FIG. 2d. In an embodiment, the lever 320 is capable of causing the suction portion 343 to move with respect to the base portion 330 into an open configuration when the lever 320 is pressed proximate to end 322. In an embodiment, the lever is capable of causing suction portion 343 to move with respect to the base portion into a closed configuration when the lever 320 is pressed proximate to end 321.

In an embodiment, the method 300 further comprises transforming the apparatus such as apparatus 300 from an open configuration to a closed configuration by pressing a lever such as lever 320 proximate to a second end such as end 321. In an embodiment, apparatus 300 further comprises a housing portion 305 for housing at least said base portion 330 having an exterior surface 306 and an opening 310 for lever 320.

In an embodiment, lever 320 is capable of being pressed with a finger proximate to end 322 to cause the suction portion to move to an open configuration. In an embodiment, lever 320 is capable of being pressed with a finger proximate to end 321 to cause suction portion 325 to move to a closed configuration. In an embodiment, lever 320 is capable of being pressed with a finger proximate to end 322 to cause suction portion 325 to move to an open configuration and the lever 320 is further capable of being pressed with the same finger proximate to end 321 to cause suction portion 325 to move to a closed configuration.

In an embodiment, lever 320 is substantially flush with exterior surface 306 when lever 320 is in a closed position. In an embodiment, apparatus 300 is capable of coupling with a surface when the apparatus is in the closed configuration.

In an embodiment, an apparatus comprises a coupling means such as coupling means 343 of FIG. 3a for coupling a device with a surface having a protruded portion such as protruded portion 345. In the embodiment, the apparatus further comprises a base portion such as base portion 330 having an opening for receiving the protruded portion and a decoupling means having first and second ends such as lever 320; the decoupling means coupled with the protruded portion. In the embodiment, the decoupling means is capable of interfacing with the base portion and moving the coupling means with respect to the base portion into open and closed configurations. In the embodiment, the decoupling means has an open position and a closed position and is capable of causing the coupling means to move with respect to the base portion into the open configuration when the decoupling means is actuated proximate to the first end such as end 322. In the embodiment, decoupling means is capable of causing the coupling means to move with respect to said base portion into a closed configuration when said decoupling means is actuated proximate to the second end such as end 321.

Without in any way limiting the scope, interpretation, or application of the claims appearing below, a technical effect of one or more of the example embodiments disclosed herein is to provide an apparatus and method for coupling and decoupling an electronic device to a surface by a pressing a lever. Another technical effect of one or more of the example embodiments disclosed herein is to provide an apparatus and method for coupling and decoupling an electronic device to a surface by a pressing a lever using a finger. Another technical effect of one or more of the example embodiments disclosed herein is to provide an apparatus and method for coupling and decoupling an electronic device to a surface by a pushing a lever with limited force.

If desired, the different functions discussed herein may be performed in a different order and/or concurrently with each other. Furthermore, if desired, one or more of the above-described functions may be optional or may be combined.

Although various aspects of the invention are set out in the independent claims, other aspects of the invention comprise other combinations of features from the described embodiments and/or the dependent claims with the features of the independent claims, and not solely the combinations explicitly set out in the claims.

It is also noted herein that while the above describes example embodiments of the invention, these descriptions should not be viewed in a limiting sense. Rather, there are several variations and modifications which may be made without departing from the scope of the present invention as defined in the appended claims.

What is claimed is:

1. An apparatus, comprising:
a suction portion having a suction element and a protruded portion;
a base portion having an opening for receiving said protruded portion;
a lever having first and second ends, said lever coupled with said protruded portion, said lever capable of interfacing with said base portion and moving said suction portion with respect to said base portion into open and closed configurations, said lever having an open position and a closed position, said lever capable of causing said suction portion to move with respect to said base portion into said open configuration when said lever is pressed proximate to said first end, said lever capable of causing said suction portion to move with respect to said base portion into said closed configuration when said lever is pressed proximate to said second end; and
a housing portion for housing at least said base portion having an exterior surface and an opening for said lever, said lever being substantially flush with said exterior surface when said lever is in said closed position.

2. An apparatus according to claim 1, wherein said suction portion capable of detachably coupling said apparatus to a surface when a lever is moved to a closed position.

3. An apparatus according to claim 1, wherein said suction portion capable of detaching said apparatus from a surface when a lever is moved to an open position.

4. An apparatus according to claim 1, wherein said lever protrudes through said opening for said lever when said lever is in said open position.

5. An apparatus according to claim 1, wherein said lever capable of being pressed with a finger proximate to said first end to cause said suction portion to move to said open configuration.

6. An apparatus according to claim 1, wherein said lever capable of being pressed with a finger proximate to said second end to cause said suction portion to move to said closed configuration.

7. An apparatus according to claim 1, wherein said lever capable of being pressed with a finger proximate to said first end to cause said suction portion to move to said open configuration and wherein said lever capable of being pressed with said finger proximate to said second end to cause said suction portion to move to said closed configuration.

8. An apparatus according to claim 1, further comprising a resilient member positioned with said protruded portion capable of biasing said suction portion toward said open configuration.

9. An apparatus according to claim 1, further comprising an electronic device coupler for removeably coupling an electronic device with said apparatus.

10. An apparatus according to claim 1, wherein a contour of an exterior surface of said lever is substantially similar to a contour of said exterior surface of said housing portion.

11. An apparatus according to claim 1, wherein said apparatus is capable of detachably coupling to a surface when said apparatus is in said closed configuration.

12. A method, comprising:
transforming an apparatus from a closed configuration to an open configuration by pressing a lever proximate to a first end of said lever;
wherein said apparatus comprises
a suction portion having a suction element and a protruded portion;
a base portion having an opening for receiving said protruded portion;
said lever having said first end and a second end, said lever coupled with said protruded portion, said lever capable of interfacing with said base portion and moving said suction portion with respect to said base portion into open and closed configurations, said lever having an open position and a closed position, said lever capable of causing said suction portion to move with respect to said base portion into said open configuration when said lever is pressed proximate to said first end, said lever capable of causing said suction portion to move with respect to said base portion into said closed configuration when said lever is pressed proximate to said second end.

13. A method according to claim 12, further comprising transforming said apparatus from an open configuration to a closed configuration by pressing said lever proximate to said second end of said lever.

14. A method according to claim 12, wherein said apparatus further comprises a housing portion for housing at least said base portion having an exterior surface and an opening for said lever.

15. A method according to claim 12, wherein said lever capable of being pressed with a finger proximate to said first end to cause said suction portion to move to said open configuration.

16. A method according to claim 12, wherein said lever capable of being pressed with a finger proximate to said second end to cause said suction portion to move to said closed configuration.

17. A method according to claim 12, wherein said lever capable of being pressed with a finger proximate to said first end to cause said suction portion to move to said open configuration and wherein said lever capable of being pressing with said finger proximate to said second end to cause said suction portion to move to said closed configuration.

18. A method according to claim 14, wherein a contour of an exterior surface of said lever is substantially similar to a contour of said exterior surface of said housing portion.

19. A method according to claim 12, wherein said apparatus is capable of coupling with a surface when said apparatus in said closed configuration.

20. An apparatus, comprising:
a coupling means for coupling a device with a surface having a protruded portion;
a base portion having an opening for receiving said protruded portion;
a decoupling means having first and second ends, said decoupling means coupled with said protruded portion, said decoupling means capable of interfacing with said base portion and moving said coupling means with respect to said base portion into open and closed configurations, said decoupling means having an open position and a closed position, said decoupling means capable of causing said coupling means to move with respect to said base portion into said open configuration when said decoupling means is actuated proximate to said first end, said decoupling means capable of causing said coupling means to move with respect to said base portion into said closed configuration when said decoupling means is actuated proximate to said second end.
